(19) United States
(12) Patent Application Publication
(10) Pub. No.: US 2026/0172050 A1
(43) Pub. Date: Jun. 18, 2026

(54) RENDERING SYSTEM FOR SEMICONDUCTOR PROCESS DATA IN SERVER-CLIENT ARCHITECTURE

(71) Applicant: Samsung Electronics Co., Ltd., Suwon-si (KR)

(72) Inventors: Yijeong Kim, Suwon-si (KR); Euiseok Kum, Suwon-si (KR); Sanghyuck Kim, Suwon-si (KR); Youngkwan Kim, Suwon-si (KR); Edward Sung, Suwon-si (KR); Eunyoung Lee, Suwon-si (KR); Bora Jeong, Suwon-si (KR); Sungmin Cho, Suwon-si (KR); Yunhyeok Jo, Suwon-si (KR); Sunyoung Han, Suwon-si (KR)

(21) Appl. No.: 19/337,318

(22) Filed: Sep. 23, 2025

(30) Foreign Application Priority Data
Dec. 17, 2024 (KR) 10-2024-0189071

(51) Int. Cl. H03M 7/30

(52) U.S. Cl. CPC H03M 7/70; H03M 7/3086; H03M 7/55; H03M 7/6005; H03M 7/6058

(57) ABSTRACT

A rendering system in a server-client architecture includes a client device and a server device configured to receive a rendering request from the client device. The server device includes (i) a collection server configured to generate, based on source data, compressed process data and metadata, (ii) a distributed server configured to store the compressed process data, and (iii) a central server configured to store the metadata and a rendering lookup table and determine whether to perform client-side rendering (CSR) or server-side rendering (SSR), based on the rendering request and the rendering lookup table. The client device is configured to, when it is determined to perform the SSR, receive the rendered data from the server device, and when it is determined to perform the CSR, receive the compressed process data.

### CROSS-REFERENCE TO RELATED APPLICATION

This application is based on and claims priority under 35 U.S.C. § 119 to Korean Patent Application No. 10-2024-0189071, filed on Dec. 17, 2024, in the Korean Intellectual Property Office, the disclosure of which is incorporated by reference herein in its entirety.

### BACKGROUND

As semiconductor manufacturing has evolved, the processes involved in producing semiconductor products have become increasingly complex and may involve a large number of sequential operations. These operations may generate various types of data, which can be associated with different stages or aspects of the manufacturing workflow.

### SUMMARY

As semiconductor structures decrease in size, a large number of unit processes (e.g., hundreds to thousands of unit processes) may need to be performed to produce a single finished semiconductor product. As semiconductor products undergo numerous unit processes, it may be difficult to identify causes of defects in semiconductor products.

To address the issue mentioned above, large amounts of semiconductor process data may be analyzed to detect equipment and/or processes that are suspected to be the cause of defects. Therefore, it is desired to render large amounts of semiconductor process data at high speed for efficient analysis of process data.

Implementations according to the present disclosure provides a system of compressing and storing process data without loss.

Implementations according to the present disclosure also provides a rendering system of rendering a large amount of process data at high speed.

However, the objects of the present disclosure are not limited to the aforementioned object, but other objects not described herein will be clearly understood by those skilled in the art from the following description.

An aspect of the present disclosure provides a rendering system in a server-client architecture, the rendering system including a client device and a server device configured to receive a rendering request from the client device, wherein the server device includes a collection server configured to obtain source data from an external data source and generate, based on the source data, compressed process data and metadata with respect to the compressed process data, a distributed server configured to store the compressed process data received from the collection server, a central server configured to store the metadata and a rendering lookup table and determine whether to perform client-side rendering (CSR) or server-side rendering (SSR), based on the rendering request and the rendering lookup table, and a computing server configured to, when it is determined to perform the SSR, receive the compressed process data from the distributed server, decode and render the compressed process data, and transmit the rendered data to the client device, and wherein the client device is configured to, when it is determined to perform the SSR, receive the rendered data from the computing server and display the rendered data, and when it is determined to perform the CSR, receive the compressed process data from the distributed server, decode and render the compressed process data, and display the rendered data, and wherein the rendering request includes information about features of process data to be rendered, and the rendering lookup table includes rendering rule information configured to determine, based on the features of the process data, whether to perform the CSR or the SSR.

Another aspect of the present disclosure provides a server device including a collection server configured to obtain source data from an external data source and generate, based on the source data, compressed process data and metadata with respect to the compressed process data, a distributed server configured to store the compressed process data received from the collection server, a central server configured to store the metadata, received from the collection server, and a rendering lookup table, and a computing server, wherein the central server is configured to receive a rendering request from a client device and determine whether to perform CSR or SSR based on the rendering request and the rendering lookup table, and wherein the distributed server is configured to transmit the compressed process data to the client device when it is determined to perform the CSR and transmit the compressed process data to the computing server when it is determined to perform the SSR, and wherein the computing server is configured to, when it is determined to perform the SSR, receive the compressed process data from the distributed server, decode and render the compressed process data, and transmit the rendered data to the client device, and wherein the rendering request includes information about features of process data to be rendered, and the rendering lookup table includes rendering rule information configured to determine, based on the features of the process data, whether to perform the CSR or the SSR.

Another aspect of the present disclosure provides a client device including a display, a storage configured to store a rendering lookup table, an input interface, a communication interface configured to communicate with a server device, and at least one processor, wherein the at least one processor is configured to receive a rendering request from a user via the input interface, determine whether to perform CSR or SSR based on the rendering request and the rendering lookup table, based on a result of a determination of whether to perform the CSR or the SSR, receive data corresponding to the result of the determination from the server device via the communication interface, and based on the received data, control the display to display an image corresponding to the rendering request, and wherein the rendering request includes information about features of process data to be rendered, and the rendering lookup table includes rendering rule information configured to determine, based on the features of the process data, whether to perform the CSR or the SSR.

### BRIEF DESCRIPTION OF THE DRAWINGS

FIG. 1 is a conceptual diagram of an example of a rendering system in a server-client architecture.

FIG. 2 is a block diagram of an example of a data mart.

FIG. 3 is a diagram illustrating an example of data collection and transmission operations of a collection server.

FIG. 4 is a diagram illustrating an example of stored data in a data mart.

FIG. 5 is a diagram illustrating an example of data compression operation of a collection server.

FIG. 6 is a diagram illustrating repeated compression based on a delta encoding technique of a collection server.

FIG. 7 is a diagram illustrating an example of a server-side rendering operation.

FIG. 8 is a diagram illustrating an example of a client-side rendering operation.

FIG. 9 is a diagram illustrating an example of a rendering lookup table.

FIG. 10 is a diagram illustrating an example of a rendering lookup table.

FIG. 11 is a block diagram of an example of a data mart.

FIG. 12 is a diagram illustrating an example of data collection and transmission operations of a collection server.

FIG. 13 is a diagram illustrating an example of stored data in a data mart.

FIG. 14 is a block diagram illustrating a physical configuration of an example of a rendering system in a server-client architecture.

FIG. 15 is a diagram illustrating an example of a server-side rendering operation.

FIG. 16 is a diagram illustrating an example of a client-side rendering operation.

FIG. 17 is a graph illustrating data displayed by an example of a rendering system in a server-client architecture.

### DETAILED DESCRIPTION

Hereinafter, implementations are described in detail with reference to the accompanying drawings. The same reference numerals are given to the same elements in the drawings, and repeated descriptions thereof are omitted.

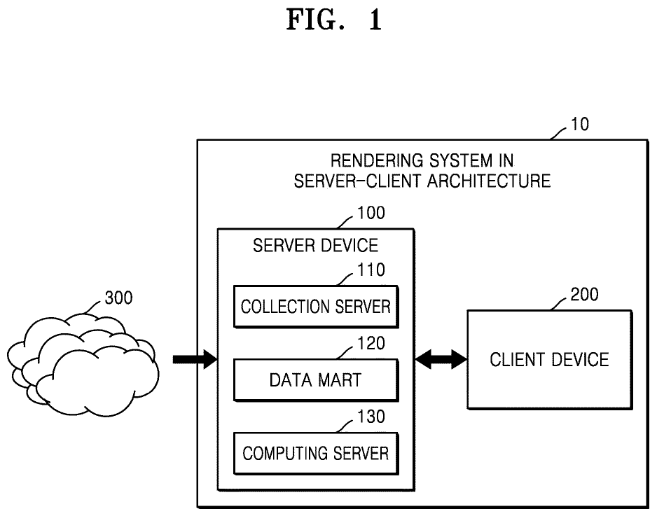

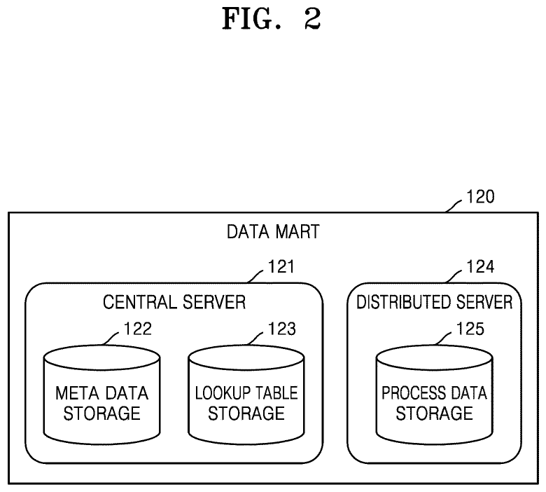

FIG. 1 is a conceptual diagram of a rendering system 10 in a server-client architecture (hereinafter, referred to as a server-client rendering system 10. FIG. 2 is a block diagram of a data mart 120.

Referring to FIG. 1, the server-client rendering system 10 can include a server device 100 and a client device 200.

The server device 100 can include a collection server 110, the data mart 120, and a computing server 130. Here, the server device 100 can be implemented as a physical server or a virtual server. For example, the server device 100 can be implemented as a plurality of physical servers, or as a plurality of virtual servers provided by a virtualization platform.

Also, the client device 200 can represent a device that requests data from the server device 100. Here, the client device 200 can be implemented as a physical computing device or as virtual machine (VM) provided by a virtualization platform. For example, the client device 200 can be implemented as a personal computer (PC) including a display, or the client device 200 can be implemented as a VM not including a display.

The collection server 110 can receive source data from an external data source 300. Here, the external data source 300 can represent a data source that provides the server device 100 with various pieces of data generated from a semiconductor manufacturing process. For example, the external data source 300 includes a plurality of semiconductor facilities. Specifically, each of the plurality of semiconductor facilities can provide the server device 100 with source data generated from various types of semiconductor manufacturing processes performed in the facility.

Here, the source data can represent data about the semiconductor manufacturing process, which is provided from the external data source 300. For example, the source data can include process data and metadata.

The process data can represent data generated before, after, and/or during a semiconductor manufacturing process, which is used to monitor and evaluate the state of the semiconductor manufacturing process. For example, the process data can include sensor data, measurement data, and yield data. In addition, the process data is not limited to the examples described above and can include other pieces of data enabling monitoring of the state of the semiconductor manufacturing process.

The metadata can represent data that includes supplementary information about the process data (e.g., information about the origin of the process data). For example, the metadata can include process information, facility information, and wafer information for the process data. Specifically, the metadata can include information about which process program generated the process data, which process step generated the process data, which facility generated the process data, which wafer generated the process data, or the like. However, the metadata is not limited to the examples described above and can include other pieces of data that provide supplementary information about the process data.

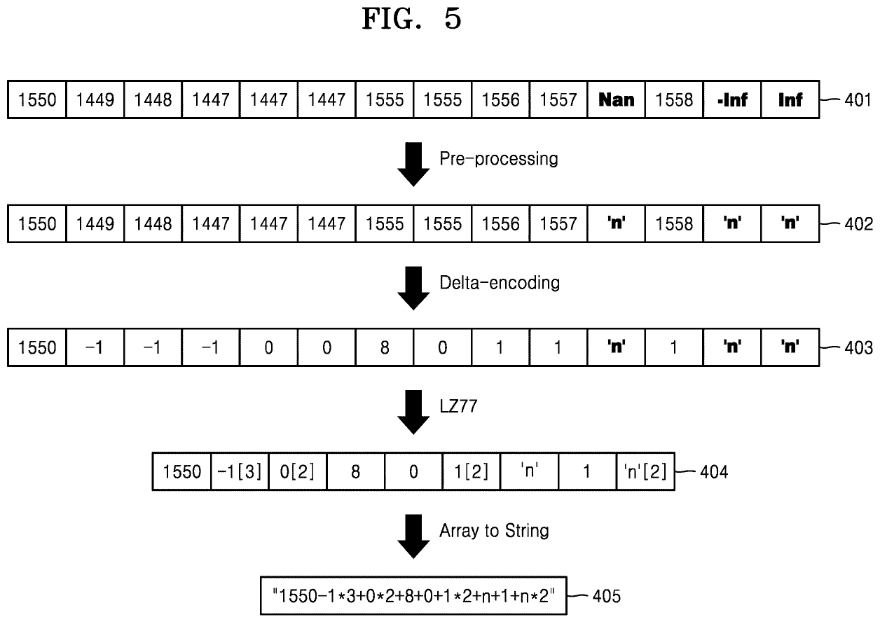

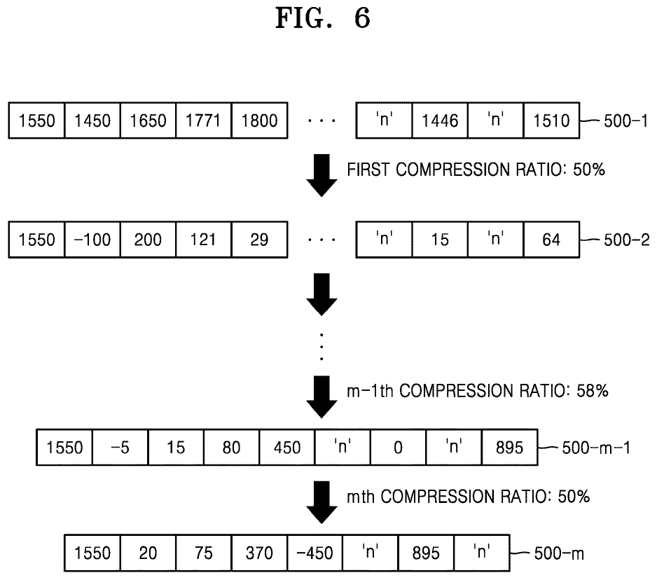

The collection server 110 can extract the process data and the metadata from the source data. Subsequently, the collection server 110 can compress the process data to generate compressed process data. For example, the collection server 110 can compress the process data at a compression ratio of 0.01 or less. The compression operation of the collection server 110 is described below in detail with reference to FIGS. 5 and 6.

The data mart 120 can include a storage unit for storing various pieces of data used to render the process data. Referring to FIG. 2, the data mart 120 can include a central server 121 and a distributed server 124. The central server 121 can include a metadata storage 122 and a lookup table storage 123. Also, the distributed server 124 can include a process data storage 125.

The central server 121 can receive a rendering request from the client device 200 and determine whether to perform client-side rendering or server-side rendering on the basis of the rendering request and a rendering lookup table.

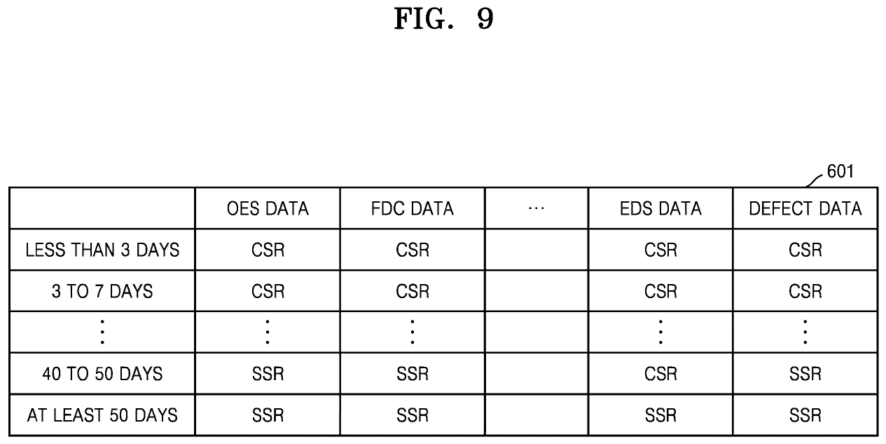

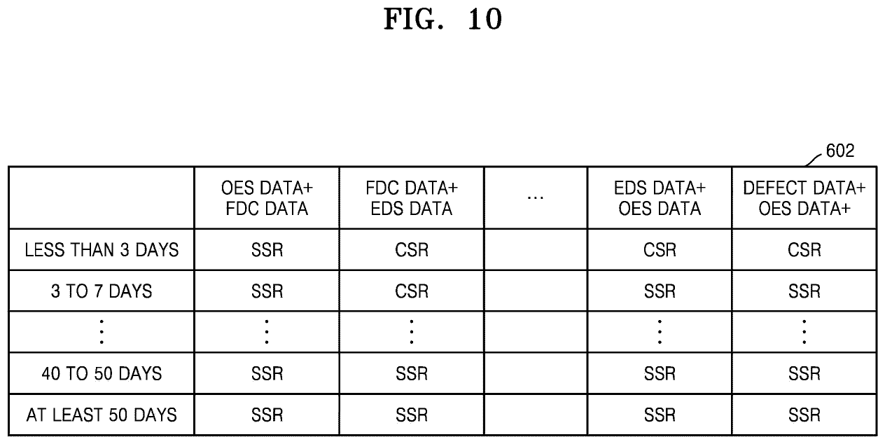

The metadata storage 122 can store the metadata received from the collection server 110. The lookup table storage 123 can store the rendering lookup table. Here, the rendering lookup table can represent a lookup table that contains rule information for determining whether to perform the client-side rendering or the server-side rendering on the basis of the features of the process data to be rendered. The rendering lookup table is described below in detail with reference to FIGS. 9 and 10.

When it is determined to perform the client-side rendering or the server-side rendering, the distributed server 124 can provide the compressed process data to the client device 200 or the computing server 130 on the basis of results of the determination. The process data storage 125 can store the compressed process data received from the collection server 110.

Specifically, when it is determined to perform the client-side rendering, the distributed server 124 can transmit the compressed process data to the client device 200. When it is determined to perform the server-side rendering, the distributed server 124 can transmit the compressed process data to the computing server 130.

The computing server 130 can represent a server that performs a computing operation required for processing the process data. Specifically, when it has been determined that the server-side rendering is to be used, the computing server 130 can perform decoding and rendering operations on the compressed process data received from the distributed server 124.

The client device 200 can display the rendered data and receive a rendering request from a user. The client device 200 can transmit, to the central server 121, the rendering request received from the user.

In addition, when it is determined to perform the client-side rendering, the client device 200 can receive the compressed process data from the distributed server 124 and perform the decoding and rendering operations on the compressed process data. The client device 200 can display the rendered data.

Also, when it is determined to perform the server-side rendering, the client device 200 can receive the rendered data from the computing server 130, and the client device 200 can display the received data.

Here, the client device 200 can be implemented as a device including a display. In this case, the client device 200 can control the display to show the rendered data. Also, the client device 200 can be connected to an external display device. In this case, the client device 200 can also transmit data and a control signal to the external display device so that the external display device displays the rendered data.

Generally, in a case in which the size of the process data to be rendered is very large, when rendering is performed on the client device 200, which has relatively limited available resources compared to the computing server 130, it can take a considerable amount of time to perform the rendering. On the other hand, when the rendering is performed by the computing server 130, which has more available resources than the client device 200 and processes complex computations in parallel, the process data can be rendered in a short period of time. Therefore, when the size of the process data to be rendered is very large, the resource limitations of the client device 200 can be overcome on the basis of performing the server-side rendering.

In addition, generally, in a case in which the size of the process data to be rendered is not large, when the computing server 130 receives the compressed process data from the distributed server 124, performs rendering, and then provides the rendered data to the client device 200, a network load can increase. On the other hand, when the client device 200 performs rendering by directly receiving the compressed process data from the distributed server 124, without going through the computing server 130, the network load can decrease. In addition, since the size of the process data to be rendered is not large, it does not take much time for the client device 200 to perform the rendering. Therefore, when the size of the process data to be rendered is not large, the network load can be reduced on the basis of performing the client-side rendering.

According to the related art, when receiving a rendering request from the client device 200, the server device 100 directly identifies the size of the process data to be rendered and determines whether to perform the client-side rendering or the server-side rendering on the basis of the size of the process data.

For example, the rendering request can include a request for “rendering of a plurality of pieces of fault detection and classification (FDC) data generated from a first facility during the last month.” In this case, the server device 100 identifies the size of “plurality of pieces of FDC data generated from the first facility during the last month” stored in the process data storage 125, and determines to perform the server-side rendering when the size is large and determines to perform the client-side rendering when the size is not large. However, as described above, it can be very inefficient that, each time a rendering request is received from the client device 200, the server device 100 directly identifies the size of the process data to be rendered and then determines whether to perform the client-side rendering or the server-side rendering.

The server-client rendering system 10 according to some implementations can determine whether to perform the client-side rendering or the server-side rendering on the basis of the rendering rule information contained in the rendering lookup table. Accordingly, the server-client rendering system 10 can determine whether to perform the client-side rendering or the server-side rendering, without directly identifying the size of the process data to be rendered. Consequently, the server-client rendering system 10 can render the process data quickly.

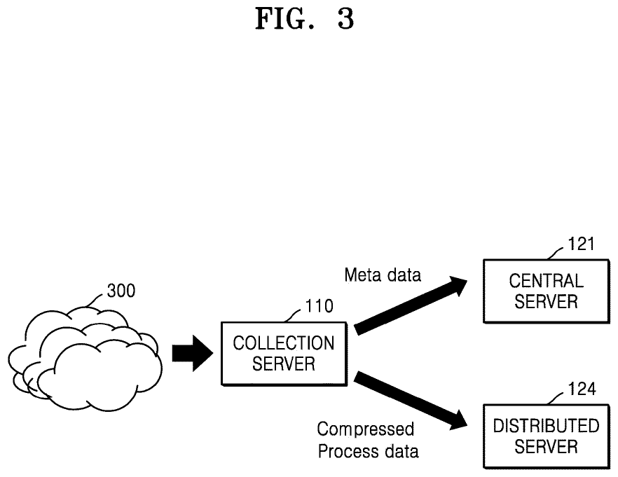

In addition, the server device 100 according to some implementations can efficiently compress and store a large size of process data. The compression and storage of a large size of process data are described below in detail with reference to FIGS. 3 to 6.

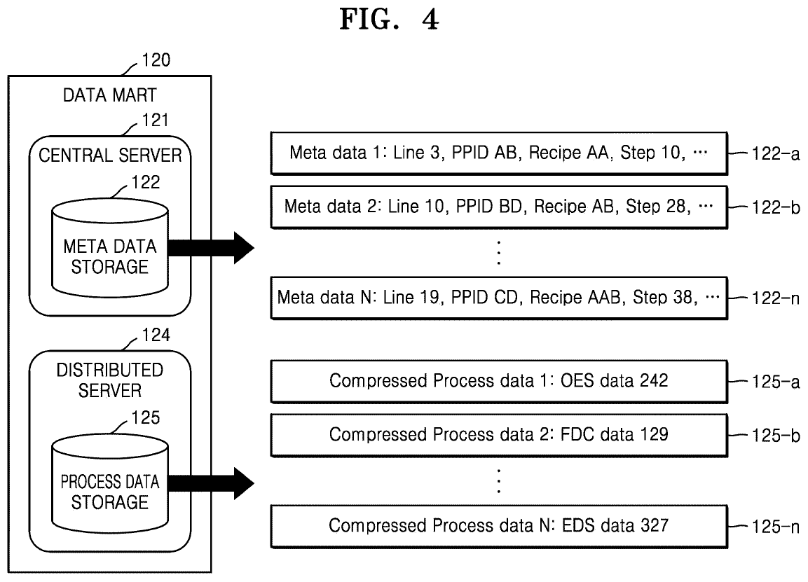

FIG. 3 is a diagram illustrating an example of data collection and transmission operations of the collection server 110. FIG. 4 is a diagram illustrating an example of the stored data in the data mart 120.

Referring to FIG. 3, the collection server 110 can receive the source data from the external data source 300, transmit the metadata to the central server 121, and transmit the compressed process data to the distributed server 124.

The collection server 110 can extract the process data and metadata from the source data and map the corresponding process data and metadata to each other. For example, the collection server 110 can assign the same identifier to the corresponding process data and metadata so that the corresponding process data and metadata can be mapped to each other.

The collection server 110 can compress the process data extracted from the source data to generate the compressed process data. Specifically, the collection server 110 can compress the process data on the basis of a lossless data compression technique. Here, the lossless compression technique can include various types of compression techniques, such as an LZ77 technique, a delta encoding technique, and a Huffman technique.

The collection server 110 can transmit the compressed process data to the distributed server 124 and transmit the metadata to the central server 121. The central server 121 can store the metadata in the metadata storage 122, and the distributed server 124 can store the compressed process data in the process data storage 125. Here, the metadata storage 122 and the process data storage 125 can be implemented as a storage, such as flash-memory, a hard-disc drive (HDD), and a solid-state drive (SSD).

A plurality of pieces of metadata contained in the metadata storage 122 and a plurality of pieces of compressed process data contained in the process data storage 125 can be mapped to each other and stored. For example, the corresponding metadata and compressed process data can be given the same identifier and mapped to each other.

Referring to FIG. 4, the metadata storage 122 can store a plurality of pieces of metadata (e.g., first metadata 122-a, second metadata 122-b, . . . , and nth metadata 122-n) and the process data storage 125 can store a plurality of pieces of compressed process data (e.g., first compressed process data 125-a, second compressed process data 125-b, . . . , and nth compressed process data 125-n). The plurality of pieces of metadata and the plurality of pieces of compressed process data can be mapped to each other and stored.

For example, the first metadata 122-a and the first compressed process data 125-a can be mapped to each other and stored in the metadata storage 122 and the process data storage 125, respectively. Specifically, the first compressed process data 125-a can represent compressed optical emission spectroscopy (OES) data that is generated from a “10th process step performed at a facility on a manufacturing line 3 (LINE 3) on the basis of a process program designated as program process ID (PPID) ‘AB’ and a process recipe designated as recipe ‘AA’.” Here, the OES data represents data that contains information about a ‘brightness value of light for each wavelength’ sensed by an OES sensor. In this case, the first metadata 122-a can represent data containing the information “manufacturing line 3, PPID AB, recipe AA, STEP 10”, and the first metadata 122-a and the first compressed process data 125-a can be mapped to each other and stored.

Based on the same principle, the second to nth metadata 122-b to 122-n can be mapped to the second to nth compressed process data 125-b to 125-n, respectively, and stored in the metadata storage 122. Although FIG. 4 shows that the metadata only includes information about the manufacturing line, the PPID, the process recipe, and the process step, this is only an example for convenience of description. The metadata can further include various pieces of supplementary information about the process data, such as the type of domain to which the process data belongs (e.g., an OES data type, an FDC data type, an energy dispersive spectroscopy (EDS) data type, etc.), the period during which the process data has been collected, the information about a facility identifier corresponding to the process data, the information about a chamber identifier corresponding to the process data, the information about a wafer identifier corresponding to the process data, and the information about a lot (LOT) identifier corresponding to the process data.

Each of the first to nth compressed process data 125-a, 125-b, . . . , and 125-n can be generated based on a lossless compression method of the collection server 110, and the compression operation of the process data by the collection server 110 is described below in detail with reference to FIGS. 5 and 6.

FIG. 5 is a diagram illustrating an example of data compression operation of the collection server 110.

Referring to FIG. 5, the collection server 110 can compress first data 401, which is the process data extracted from the source data, to generate fifth data 405, which is the compressed process data.

The collection server 110 can perform pre-processing on the first data 401 to generate second data 402. The collection server 110 can perform the pre-processing to remove noise from the first data 401. The first data 401 can represent raw data, which is an array containing a plurality of components. For example, the collection server 110 can replace, with the letter “n,” components corresponding to a value of “Nan,” a value of “Inf,” or a value of “-Inf” among the plurality of components in the first data 401.

In addition, based on the type of domain to which the first data 401 belongs, the collection server 110 can perform pre-processing corresponding to the type of the domain. For example, when the first data 401 corresponds to the OES data type, the collection server 110 can regard an intensity value of light exceeding 60035 (a.u) among intensity values contained in the first data 401 as noise and replace this intensity value with the letter “n.”

However, the pre-processing operation of the collection server 110 on the OES data type described above is only one example presented for convenience of description, and the collection server 110 can also perform a pre-processing operation corresponding to each of other types of domains. For example, when the first data 401 is of the FDC data type, the collection server 110 can only perform a pre-processing operation of replacing the components corresponding to the value of “Nan,” the value of “Inf,” and the value of “-Inf” with the letter “n.” The pre-processing operation corresponding to each of the domain types described above can be determined by specialized knowledge of a user (e.g., a process engineer).

The collection server 110 can perform compression on the second data 402 on the basis of the delta encoding technique, thereby generating third data 403. Here, the delta encoding technique can represent a compression method of reducing the size of data by storing only the amount of change (delta) between two consecutive components. While maintaining the value of a first component of the second data 402, the collection server 110 can store the amount of change between consecutive components with respect to the remaining components.

Specifically, as shown in FIG. 5, the collection server 110 can maintain the value of “1550,” which is the first component of the second data 402. On the other hand, the collection server 110 can store, as a value of a second component, “−1” obtained by subtracting “1550,” which is a first component of the second data 402, from “1449,” which is a second component of the second data 402. Also, the collection server 110 can store, as a value of a third component, “−1” obtained by subtracting “1449,” which is the second component of the second data 402, from “1448,” which is a third component of the second data 402. Also, the collection server 110 can perform compression based on the delta encoding technique while ignoring the “n” component. For example, since the 11th, 13th, and 14th components of the second data 402 are “n,” the collection server 110 can store, as a 12th component, “1” which is the amount of change between a 12th component “1558” and a 10th component “1557” of the second data 402.

The collection server 110 can store, as the third data 403, the data compressed based on the delta encoding technique. FIG. 5 shows that the collection server 110 performs compression based on the delta encoding technique only once, but this is only an example. The collection server 110 can repeatedly perform compression based on the delta encoding technique n times (where n is a natural number greater than or equal to 2) to increase the compression ratio of the data. This is described below in detail with reference to FIG. 6.

The collection server 110 can perform compression on the third data 403 on the basis of the LZ77 technique, thereby generating fourth data 404. Here, the LZ77 technique can represent a compression method that reduces the size of data by searching for repeated components and storing only information about values and lengths of the repeated components. The collection server 110 can identify repeated patterns in the third data 403 and store only information on component values of the repeated patterns and the length of the repeated patterns.

Specifically, as shown in FIG. 5, the collection server 110 can identify that the values of the second, third, and fourth components of the third data 403 are continuously “−1.” The collection server 110 can store the values of the second to fourth components of the third data 403 as “−1[3].” In addition, the collection server 110 can identify that the values of the 13th and 14th components of the third data 403 are continuously “n.” The collection server 110 can store the values of the 13th and 14th components as “n[2].” The collection server 110 can convert the repeated patterns into simple information (the values of components and the lengths of repeated patterns) and store this simple information to generate the fourth data 404.

The collection server 110 can convert the fourth data 404 into string-type data to generate the fifth data 405. The compression method based on the conversion of data into the string type can be particularly efficient for large volumes of data. The collection server 110 can identify the fifth data 405 as compressed process data and transmit the compressed process data to the distributed server 124.

In the description with reference to FIG. 5, it has been only described that the collection server 110 can perform the pre-processing on raw process data and perform all of the compression based on the delta encoding technique, the compression based on the LZ77 technique, and the compression based on the conversion of data into the string type, thereby generating the compressed process data. However, the collection server 110 can omit a specific compression method among the compression methods described above. For example, the collection server 110 can perform the pre-processing on the raw process data and then perform only the compression based on the delta encoding technique, thereby generating the compressed process data.

FIG. 6 is a diagram illustrating the repeated compression based on the delta encoding technique of the collection server 110.

Referring to FIG. 6, the collection server 110 can repeat compression based on the delta encoding technique. In addition, the data compressed based on the repeated compression by using the delta encoding technique can be further compressed on the basis of the LZ77 technique and/or on the basis of the conversion to the string type.

The collection server 110 can repeatedly perform compression based on the delta encoding technique when an mth compression ratio is equal to or greater than an m-1th compression ratio (where m is a natural number greater than or equal to 2). Here, the mth compression ratio can represent the compression ratio in compression based on an mth performed delta encoding technique. For example, a first compression ratio can represent the compression ratio in compression based on a first performed delta encoding technique. The first compression ratio can represent the ratio of the size of a second array 500-2 to the size of a first array 500-1.

For example, when the first compression ratio is 50% and a second compression ratio is 52%, the second compression ratio is greater than or equal to the first compression ratio. Accordingly, the collection server 110 can perform compression based on the delta encoding technique on the second array 500-2, thereby generating a third array.

When the mth compression ratio is less than the m-1th compression ratio, the collection server 110 can stop performing repeated compression based on the delta encoding technique. For example, when the m-1th compression ratio is 58% and the mth compression ratio is 50%, the mth compression ratio is less than the m-1th compression ratio. Therefore, the collection server 110 can stop compression based on the delta encoding technique. In this case, the collection server 110 can perform compression based on the LZ77 technique or perform conversion to string-type data, on an mth array 500-m that has been generated by performing compression based on an mth delta encoding technique, thereby generating the compressed process data.

In other implementations, when the size of the data that has undergone pre-processing exceeds a critical size, the collection server 110 can repeatedly perform compression based on the delta encoding technique so that the compression ratio for the pre-processed data becomes 0.01 or less. Here, the critical size represents a value defined by a user or a system, which can be in a range of about 500 MB to about 1 GB. Also, the compression ratio for pre-processed data can represent the ratio of the size of compressed data to the size of pre-processed data.

For example, when the critical size is 1 GB and the size of the first array 500-1, which has the pre-processed data, is 1.2 GB, the collection server 110 can repeatedly perform compression based on the delta encoding technique so that the size of the data is reduced to about 12 MB or less.

As described above, the collection server 110 can significantly reduce the size of data while compressing a large size of raw process data based on a lossless compression technique. Rendering operation of the server-client rendering system 10 is described in detail with reference to the following diagrams.

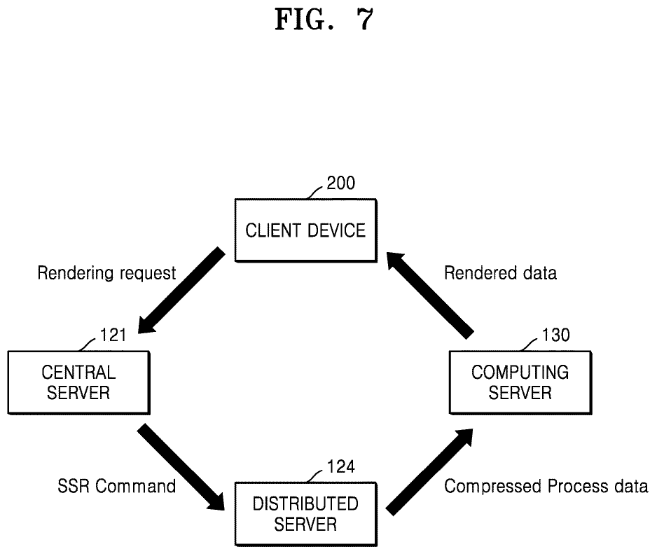

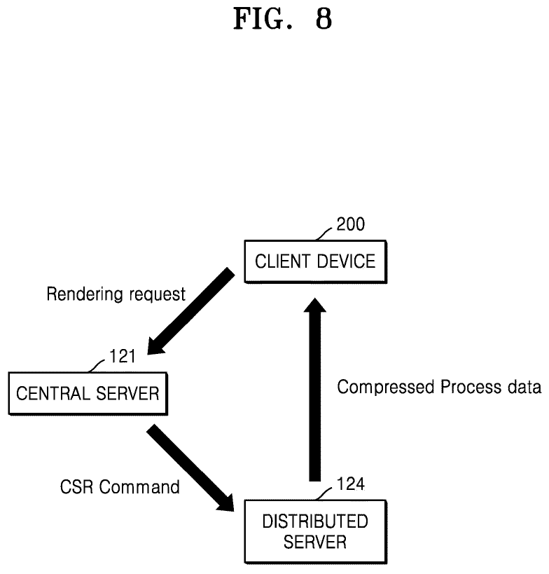

FIG. 7 is a diagram illustrating an example of a server-side rendering operation, and FIG. 8 is a diagram illustrating an example of a client-side rendering operation.

Referring to FIG. 7, the client device 200 can transmit the rendering request to the central server 121. The central server 121 can determine to perform the server-side rendering on the basis of the rendering request and the rendering lookup table.

The central server 121 can obtain information about the features of process data to be rendered, on the basis of the rendering request. The rendering request can include information about a domain of the process data, information about a search period of the process data, information about a process program of the process data, information about a facility related to the process data, and/or information about a process step related to the process data.

For example, the rendering request can include a request to “render OES data for the processes performed based on the process program corresponding to PPID AA and the process recipe corresponding to RECIPE AC at a 10th facility located on a third manufacturing line during the period of Dec. 1, 2024 to December 5, 2024.” Based on the rendering request, the central server 121 can obtain information indicating that the domain of the process data to be rendered is of the “OES data type,” the search period of the process data is between “December 1, 2024 and December 5, 2024,” the identifier of the process program in the process data is “PPID AA,” the recipe of the process program is “RECIPE AC,” and the facility related to the process data is the “10th facility located on the third manufacturing line.”

The central server 121 can determine to perform the server-side rendering on the basis of information about the features of the process data to be rendered and the rendering lookup table. A process, in which the central server 121 determines whether to perform the client-side rendering or the server-side rendering on the basis of information about the features of the process data and the rendering lookup table, is described below in detail with reference to FIGS. 9 and 10.

The central server 121 can identify the compressed process data, which is to be transmitted to the computing server 130 by the distributed server 124, based on information about the features of the process data to be rendered and information about the metadata.

The central server 121 can obtain information about the features of process data to be rendered, on the basis of the rendering request. The central server 121 can identify pieces of metadata corresponding to the information about the features described above and then identify, as the compressed process data to be rendered, pieces of compressed process data respectively mapped to the pieces of identified metadata. The central server 121 can transmit, to the distributed server 124, a server-side rendering (SSR) command for transmitting the pieces of compressed process data to be rendered to the computing server 130.

The distributed server 124 can receive the SSR command and then transmit the pieces of compressed process data to be rendered to the computing server 130 on the basis of the SSR command. The computing server 130 can decode and render the pieces of compressed process data received from the distributed server 124 and transmit the rendered data to the client device 200. The client device 200 can display the rendered data without additional rendering computations.

Referring to FIG. 8, the client device 200 can transmit the rendering request to the central server 121. The central server 121 can determine to perform the client-side rendering on the basis of the rendering request and the rendering lookup table.

When it is determined to perform the client-side rendering, the central server 121 can transmit, to the distributed server 124, a client-side rendering (CSR) command for transmitting the compressed process data to be rendered to the client device 200.

The distributed server 124 can receive the CSR command and then transmit the compressed process data to be rendered to the client device 200 on the basis of the CSR command. The client device 200 can decode and render the received compressed process data. The client device 200 can display the rendered data.

FIG. 9 is a diagram illustrating an example of a rendering lookup table 601.

Referring to FIG. 9, the rendering lookup table 601 can include rendering rule information used to determine whether to perform the client-side rendering or the server-side rendering, based on the information about the domain and the information about the search period for the process data.

In some implementations, the rendering lookup table 601 can include a two-dimensional lookup table. A first dimension (each of a plurality of columns) can be defined as the domain of process data to be rendered, and a second dimension (each of a plurality of rows) can be defined as the search period of process data to be rendered. The rendering lookup table 601 can include rendering rule information defining whether to perform the client-side rendering or the server-side rendering on the basis of the domain and the search period that are defined in the first dimension and the second dimension, respectively.

For example, when the rendering request includes a request to “render OES data collected during the period of Dec. 1, 2024 to December 06, 2024,” the central server 121 can determine to perform client-side rendering (CSR) on the basis of the rendering request and the rendering lookup table 601. In another example, when the rendering request includes a request to “render OES data collected during the period of Nov. 1, 2024 to December 11, 2024,” the central server 121 can determine to perform server-side rendering (SSR) on the basis of the rendering request and the rendering lookup table 601.

As the examples described above, even if the domains of the process data to be rendered have the same “OES data type,” the CSR can be appropriate depending on the search period of the process data, or the SSR can be more appropriate. In other words, the rendering lookup table 601 can include rendering rule information corresponding to various types of rendering requests.

Here, the rendering lookup table 601 in two dimensions shown in FIG. 9 is only an example for convenience of description, and the rendering lookup table 601 can include x-dimensions (where x is a natural number greater than or equal to 3).

In some implementations, the rendering lookup table 601 can include a three-dimensional lookup table. In this case, a first dimension can be defined as a domain of process data, a second dimension can be defined as a search period of process data, and a third dimension can be defined as one of a process identifier (Process id) of process data, a process recipe identifier, a manufacturing line identifier for process data, a facility identifier, or a process step identifier of process data. The rendering lookup table 601 having the three-dimensional lookup tables can include rendering rule information that defines whether to perform the CSR or the SSR on the basis of the features of the process data defined in each of the dimensions.

In other words, the rendering rule information contained in the rendering lookup table 601 can include information that defines whether to perform the CSR or the SSR on the basis of the process program information about the process data. Here, the process program information about the process data can include information about at least one of the process identifier (Process id) and the process recipe identifier of the process data.

In addition, the rendering rule information contained in the rendering lookup table 601 can include information that defines whether to perform the CSR or the SSR on the basis of the facility information about the process data. Here, the facility information about the process data can include information about at least one of the manufacturing line identifier and the facility identifier for the process data.

In addition, the rendering rule information contained in the rendering lookup table 601 can include information that defines whether to perform the CSR or the SSR on the basis of the process step information about the process data.

The rendering lookup table 601 can include lookup tables of other dimensions, such as four, five, and six dimensions, and the plurality of dimensions can be respectively defined by the plurality of features relating to the process data described above.

FIG. 10 is a diagram illustrating an example of a rendering lookup table 602.

Referring to FIG. 10, the rendering lookup table 602 can include rendering rule information used to determine whether to perform the CSR or the SSR based on the information about the domain and the information about the search period for the process data.

The rendering request can include a request to “render a plurality of pieces of process data corresponding to different domains.” For example, the rendering request can include a request to “render OES data and FDC data together for simultaneous analysis of OES data and FDC data collected during the period of Dec. 1, 2024 to December 02, 2024.”

In some implementations, the rendering lookup table 602 can include a two-dimensional lookup table. A first dimension (each of a plurality of columns) can be defined as a combination of the domains of process data to be rendered, and a second dimension (each of a plurality of rows) can be defined as the search period of process data to be rendered. The rendering lookup table 602 can include rendering rule information defining whether to perform the CSR or the SSR on the basis of the combination of the domains and the search period that are defined in the first dimension and the second dimension, respectively.

When the rendering request includes a request to “render OES data and FDC data together for simultaneous analysis of OES data and FDC data collected during the period of Dec. 1, 2024 to December 02, 2024,” the central server 121 can determine to perform the SSR on the basis of the rendering request and the rendering lookup table 602. In another example, when the rendering request includes a request to “render together EDS data and OES data collected during the period of Dec. 1, 2024 to December 02, 2024,” the central server 121 can determine to perform CSR on the basis of the rendering request and the rendering lookup table 602.

As the example described above, even if the search periods for the process data to be rendered are the same as “December 01, 2024 to December 02, 2024,” the CSR can be appropriate depending on the combination of domains of the process data, or the SSR can be more appropriate. In other words, the rendering lookup table 602 can include rendering rule information corresponding to each of the other combinations of domains.

FIG. 10 shows only the combination of two domains (e.g., OES data+FDC data), but this is only an example. The rendering lookup table 602 can further include rendering rule information that determines whether to perform the CSR or the SSR on the basis of a combination of two or more domains and the search period of the process data.

In addition, as described with reference to FIG. 9, the rendering lookup table 602 can include lookup tables of other dimensions, such as four, five, and six dimensions, and the plurality of dimensions can be respectively defined by the plurality of features relating to the process data.

As described above with reference to FIGS. 9 and 10, the server device 100 can quickly determine whether to perform the CSR or the SSR on the basis of the rendering rule information defined in the rendering lookup table.

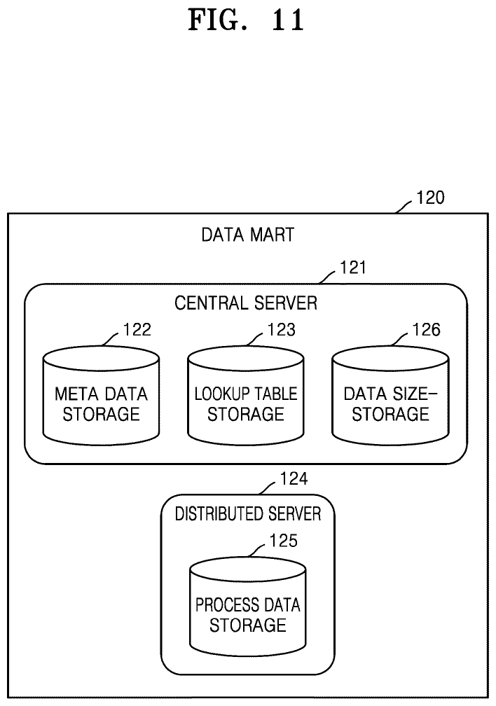

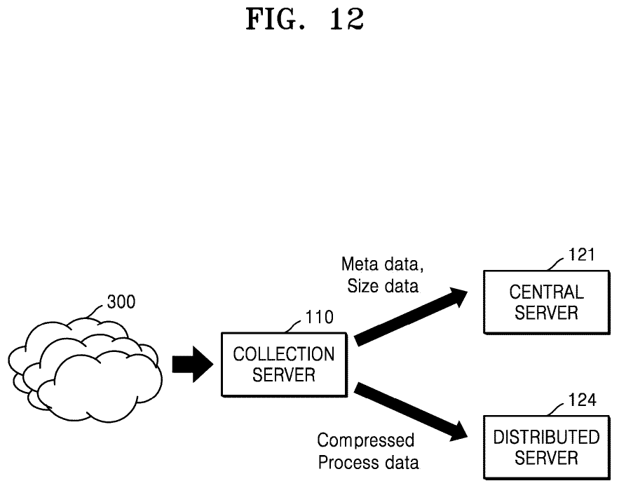

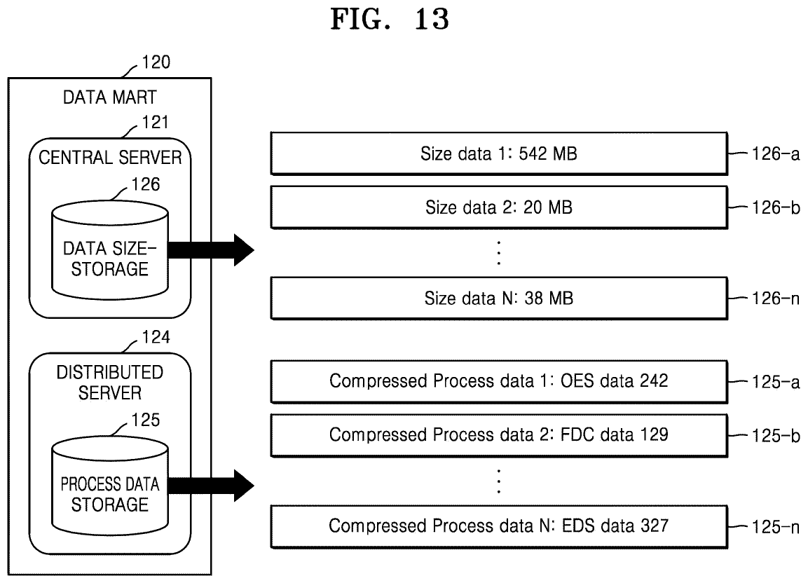

FIG. 11 is a block diagram of the data mart 120, and FIG. 12 is a diagram illustrating an example of data collection and transmission operations of the collection server 110. FIG. 13 is a diagram illustrating an example of the stored data in the data mart 120.

In the description with reference to FIGS. 11 to 13, repeated descriptions as those given above with reference to FIGS. 1 to 4 are omitted. Referring to FIG. 11, the central server 121 can further include a data size-storage 126. The data size-storage 126 can be implemented as a storage, such as flash-memory, an HDD, and an SSD. The data size-storage 126 can include information about the size of the process data.

Referring to FIG. 12, the collection server 110 can extract the process data, the metadata, and the size data from the source data received from an external data source. Here, the size data can include the size information of the raw process data. The collection server 110 can compress the process data to generate the compressed process data and can transmit the compressed process data to the distributed server 124. In addition, the collection server 110 can transmit the metadata and the size data to the central server 121.

The collection server 110 can identify the size of the process data before compressing the process data and generate the size data corresponding to the process data. The collection server 110 can map the corresponding process data, metadata, and size data to each other. For example, the collection server 110 can assign the same identifier to the corresponding process data, metadata, and size data so that the corresponding process data, metadata, and size data can be mapped to each other.

Referring to FIG. 13, the data size-storage 126 can store a plurality of pieces of size data (e.g., first size data 126-a, second size data 126-b, . . . , and nth size data 126-n). For example, the first size data 126-a can be mapped to the first compressed process data 125-a stored in the process data storage 125 and the first metadata 122-a stored in the metadata storage 122 shown in FIG. 4 and can be then stored in the data size-storage 126. Specifically, the first metadata 122-a, the first compressed process data 125-a, and the first size data 126-a can include the same identifier.

In some implementations, the central server 121 can determine whether to perform the CSR or the SSR on the basis of the rendering request and the size data stored in the data size-storage 126. The central server 121 can obtain information about the features of process data to be rendered, on the basis of the rendering request. The central server 121 can identify the pieces of compressed process data to be rendered, based on the information about the features of the process data and the metadata. When the compressed process data to be rendered is identified, the central server 121 can identify the total size of the process data to be rendered, based on pieces of the size data respectively mapped to pieces of the identified compressed process data.

For example, when the compressed process data to be rendered is identified as the first compressed process data 125-a, the second compressed process data 125-b, and the nth compressed process data 125-n, the central server 121 can identify the first size data 126-a, the second size data 126-b, and the nth size data 126-n, which are mapped to the first compressed process data 125-a, the second compressed process data 125-b, and the nth compressed process data 125-n, respectively. The central server 121 can identify that the total size of the process data to be rendered is 600 MB (542 MB+20 MB+38 MB) on the basis of the first size data 126-a, the second size data 126-b, and the nth size data 126-n.

The central server 121 can determine to perform the SSR when the total size of the process data to be rendered is greater than or equal to a predetermined size value, and can determine to perform the CSR when the total size of the process data to be rendered is less than the predetermined size value. Here, the predetermined size value can be determined based on the amount of available resources of the client device 200 and/or the computing server 130, or can be determined by a user (e.g., a process engineer). For example, the predetermined size value can be in a range of about 100 GB to about 1 TB.

In some implementations, the predetermined size value can be 1 TB. In this case, the central server 121 can determine to perform the SSR when the total size of the process data to be rendered is greater than or equal to 1 TB and determine to perform the CSR when less than 1 TB.

As described above, the server device 100 according to some implementations can store the size data including the size information about the raw process data, and can also determine whether to perform the CSR or the SSR on the basis of the stored size data.

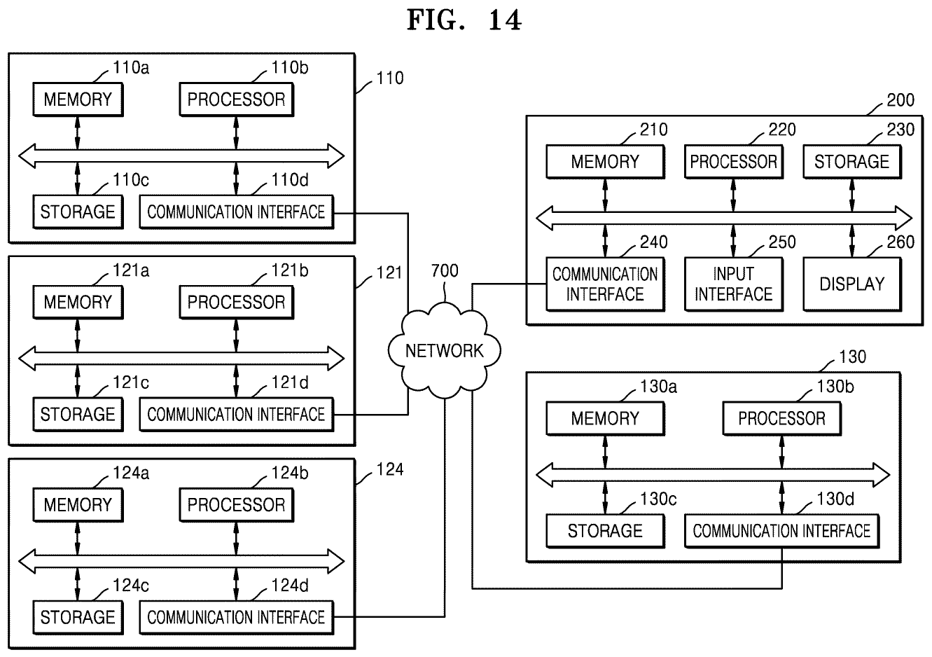

FIG. 14 is a block diagram illustrating a physical configuration of a server-client rendering system.

Referring to FIG. 14, the collection server 110, the central server 121, the distributed server 124, and the computing server 130 can each include a processor, memory, storage, and a communication interface. The collection server 110, the central server 121, the distributed server 124, the computing server 130, and the client device 200 can communicate with each other via a network 700.

The collection server 110 can include memory 110a and a processor 110b. The processor 110b can control all operations of the collection server 110 and access the memory 110a to execute instructions and/or data loaded into the memory 110a.

The processor 110b can be provided as a general-purpose processor, a dedicated processor, or an application processor. In addition, the processor 110b can include one or more central processing unit (CPU) cores, and can further include a controller for controlling the memory 110a and/or the storage 110c. According to some implementations, the processor 110b can further include an accelerator, which is a dedicated circuit for high-speed data computation. The memory 110a can include volatile memory, such as double data rate synchronous dynamic random-access memory (DDR SDRAM), high bandwidth memory (HBM), a hybrid memory cube (HMC), a dual in-line memory module (DIMM), an Optane DIMM, and a non-volatile DIMM (NVMDIMM). However, the memory 110a is not limited to the examples described above. The memory 110a can be provided in the same package as the processor 110b.

According to implementations, the number of memories 110a and the number of processors 110b in the collection server 110 can be selected in various numbers. In some implementations, the memory 110a and the processor 110b can provide a memory-processor pair. In other implementations, the number of memories 110a can be different from the number of processors 110b.

The storage 110c can include non-volatile memory that stores data irrespective of whether or not power is supplied thereto. The storage 110c can have a relatively larger storing size than the memory 110a.

A communication interface 110d can establish a communication channel with an external server and/or external devices via the network 700, and can communicate with the external server and/or the external devices via the network 700. The communication interface 110d can include a wireless communication module or a wired communication module. In some implementations, the communication interface 110d can include a network interface card (NIC) and a network adapter.

Here, the network 700 can be formed by using a fiber channel (FC) or Ethernet. Here, FC can include a medium used for relatively high-speed data transmission, and an optical switch that provides high performance/high availability can be used. In some implementations, the network 700 can include a storage area network (SAN) or a TCP/IP-based network.

In the description above, only the physical configuration of the collection server 110 are briefly described. A physical configuration of each of the central server 121, the distributed server 124, and the computing server 130 is the same as that described above, and thus, descriptions thereof are omitted.

The client device 200 can include memory 210, a processor 220, storage 230, a communication interface 240, an input interface 250, and a display 260.

The processor 220 can control all operations of the client device 200 and access the memory 210 to execute instructions and/or data loaded into the memory 210.

The processor 220 can be provided as a general-purpose processor, a dedicated processor, or an application processor. In addition, the processor 220 can include one or more CPU cores, and can further include a controller for controlling the memory 210 and/or storage 230. According to some implementations, the processor 220 can further include an accelerator, which is a dedicated circuit for high-speed data computation. The memory 210 can include volatile memory, such as DDR SDRAM, HBM, an HMC, a DIMM, an Optane DIMM, and an NVMDIMM. However, the memory 210 is not limited to the examples described above. The memory 210 can be provided in the same package as the processor 220.

According to implementations, the number of memories 210 and the number of processors 220 in the client device 200 can be selected in various numbers. In some implementations, the memory 210 and the processor 220 can provide a memory-processor pair. In other implementations, the number of memories 210 can be different from the number of processors 220.

The storage 230 can include non-volatile memory that stores data irrespective of whether or not power is supplied thereto. The storage 230 can have a relatively larger storing size than the memory 210.

The communication interface 240 can establish a communication channel with an external server and/or external devices via the network 700, and can communicate with the external server and/or the external devices via the network 700. The communication interface 240 can include a wireless communication module or a wired communication module. In some implementations, the communication interface 240 can include an NIC and a network adapter.

The input interface 250 can receive a rendering request from a user. For example, the input interface 250 can include a keyboard, a touch panel, and/or a microphone. When the input interface 250 includes the keyboard, the input interface 250 can receive the rendering request from the user through a keyboard input from the user.

The display 260 can display an image. Specifically, the display 260 can display an image corresponding to the rendering request received from the user. For example, the image corresponding to the rendering request can include a “graph visualizing a plurality of pieces of OES data.”

In the description above, it has been described that the client device 200 can include the input interface 250 and the display 260, but the client device 200 may not include the input interface 250 and the display 260.

In some implementations, the client device 200 may not include the input interface 250. In this case, the client device 200 can receive the rendering request via the communication interface 240. Specifically, the client device 200 can communicate with an external user terminal via the communication interface 240. Here, the external user terminal represents a device that interacts directly with the user, which can be provided as a PC of the user. The client device 200 can receive the rendering request of the user from the external user terminal via the communication interface 240.

In some implementations, the client device 200 may not include the display 260. In this case, the client device 200 can be connected to the external display device via the communication interface 240. The client device 200 can transmit rendered data to the external display device via the communication interface 240, and the external display device can display the rendered data.

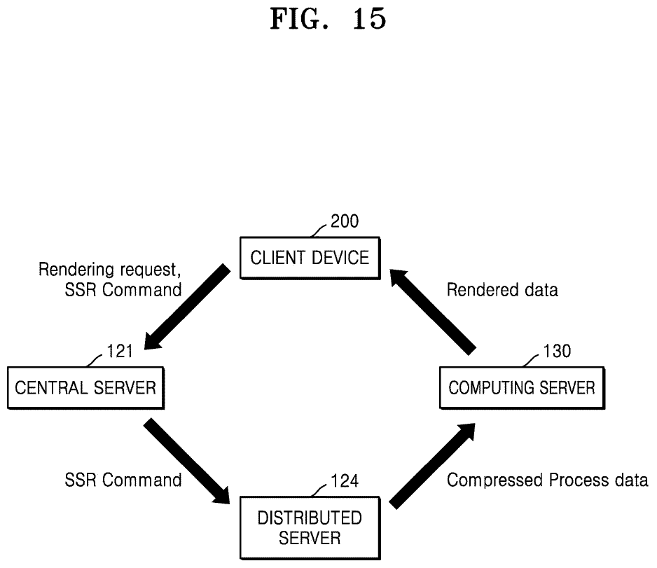

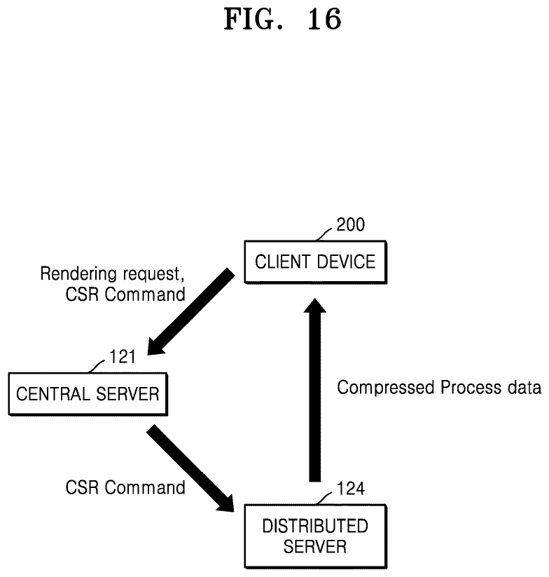

As described above, the client device 200 can include storage, such as the memory 210 and the storage 230. The rendering lookup table described with reference to FIGS. 9 and 10 can also be stored in the storage of the client device 200. In this case, the client device 200 can also determine whether to perform the CSR or the SSR on the basis of the rendering request and the rendering lookup table. This is described below in detail with reference to FIGS. 15 and 16.

FIG. 15 is a diagram illustrating an example of an SSR operation, and FIG. 16 is a diagram illustrating an example of a CSR operation.

The client device 200 can determine whether to perform the CSR or the SSR on the basis of the rendering lookup table stored in the memory 210 or the storage 230 and the rendering request. A method of determining whether to perform the CSR or the SSR in the client device 200 can be performed based on the same principle as the “method of determining whether to perform the CSR or the SSR in the central server 121” described above, and thus, detailed descriptions thereof are omitted.

Based on the result of determining whether to perform the CSR or the SSR, the client device 200 can receive data corresponding to the result of the determination via the communication interface 240.

In some implementations, the client device 200 can determine to perform the SSR. In this case, as shown in FIG. 15, the client device 200 can transmit the SSR command and the rendering request to the central server 121 so that the rendered data is transmitted to the client device 200.

The central server 121 can identify the compressed process data to be rendered, on the basis of the rendering request and the metadata. The central server 121 can transmit, to the distributed server 124, the SSR command for transmitting the identified compressed process data to the computing server 130.

The distributed server 124 can transmit the compressed process data to the computing server 130 on the basis of the SSR command. The computing server 130 can perform decoding and rendering on the compressed process data, and can transmit the rendered data to the client device 200.

The client device 200 can receive the rendered data from the computing server 130 via the communication interface 240. The client device 200 can control the display 260 to display the rendered data.

In some implementations, the client device 200 can determine to perform the CSR. In this case, as shown in FIG. 16, the client device 200 can transmit the CSR command and the rendering request to the central server 121 so that the compressed process data is transmitted to the client device 200.

The central server 121 can identify the compressed process data to be rendered, on the basis of the rendering request and the metadata. The central server 121 can transmit, to the distributed server 124, the CSR command for transmitting the identified compressed process data to the client device 200.

The distributed server 124 can transmit the compressed process data to the client device 200 on the basis of the CSR command. The client device 200 can receive the compressed process data from the distributed server 124 via the communication interface 240. The client device 200 can perform decoding and rendering on the compressed process data and control the display 260 to display the rendered data.

As described above, when the rendering lookup table is stored in the client device 200, the client device 200 can directly determine whether to perform the CSR or the SSR on the basis of the rendering lookup table and the rendering request. Accordingly, the client device 200 according to some implementations can quickly display an image corresponding to the rendering request.

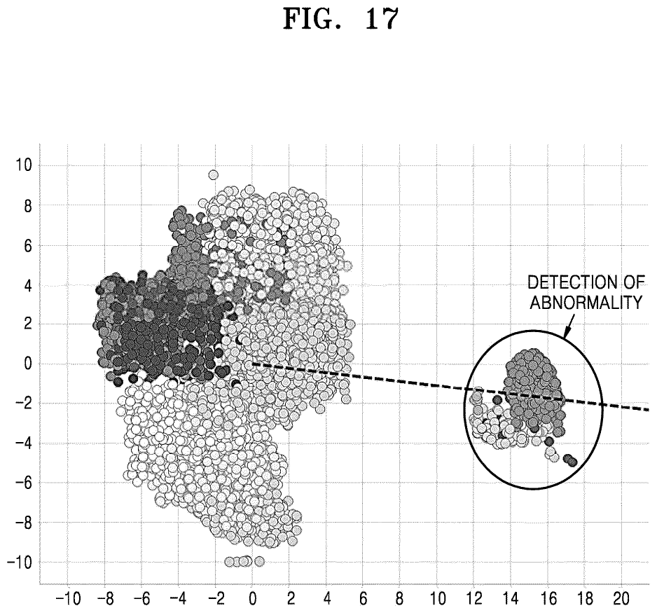

FIG. 17 is a graph illustrating data displayed by the server-client rendering system 10.

Referring to FIG. 17, the server-client rendering system 10 can render FDC data for 10,000 wafers and quickly display a principal component analysis (PCA) graph.

In a rendering system according to the related art, the size of FDC data for 10,000 wafers is identified, and then, it is determined whether to perform CSR or SSR on the basis of the identified size. However, the server-client rendering system 10 according to some implementations can quickly determine whether to perform CSR or SSR on the basis of the rendering lookup table. Accordingly, the server-client rendering system 10 can perform rendering at a speed that is at least about 5 times to about 10 times as fast as that according to the related art.

A user can quickly identify the cause of a defect in a wafer, such as detecting an abnormal facility, through a graph in which large-size data is visualized (e.g., the graph in FIG. 17).

As described above, the server-client rendering system 10 according to some implementations can efficiently compress and store a large size of process data and quickly render and display the large size of process data corresponding to the rendering request. Accordingly, the effect of quickly detecting (or identifying) the facility and/or process that causes the defect can be obtained.

While the inventive concept has been particularly shown and described with reference to implementations thereof, it will be understood that various changes in form and details can be made therein without departing from the spirit and scope of the following claims.

What is claimed is:

1. A rendering system in a server-client architecture, the rendering system comprising:
a client device; and
a server device configured to receive a rendering request from the client device,
wherein the server device comprises:
a collection server configured to (i) obtain source data from an external data source and (ii) generate, based on the source data, compressed process data and metadata with respect to the compressed process data,
a distributed server configured to store the compressed process data received from the collection server,
a central server configured to (i) store the metadata and a rendering lookup table and (ii) determine to perform client-side rendering (CSR) or server-side rendering (SSR), based on the rendering request and the rendering lookup table, and
a computing server configured to, based on determining to perform the SSR, receive the compressed process data from the distributed server, decode and render the compressed process data, and transmit the rendered data to the client device, and
wherein the client device is configured to:
based on determining to perform the SSR, receive the rendered data from the computing server and display the rendered data, and
based on determining to perform the CSR, receive the compressed process data from the distributed server, decode and render the compressed process data, and display the rendered data, and
wherein the rendering request comprises information about features of process data to be rendered, and
wherein the rendering lookup table comprises rendering rule information for determining to perform the CSR or the SSR, based on the features of the process data.

2. The rendering system of claim 1, wherein the collection server is configured to:
extract the process data from the source data that is obtained from the external data source;
perform pre-processing on the process data to remove noise from the process data;
compress the pre-processed data based on a delta encoding technique;
compress, based on an LZ77 technique, the data that has been compressed based on the delta encoding technique; and
convert, into a string, the data that has been compressed based on the LZ77 technique, thereby generating the compressed process data.

3. The rendering system of claim 2, wherein the collection server is configured to, based on the delta encoding technique, perform n repetitions of compression on the pre-processed data, where n is a natural number greater than or equal to 2.

4. The rendering system of claim 3, wherein the collection server is configured to:
based on an mth compression ratio being greater than or equal to an m-1th compression ratio, where m is a natural number greater than or equal to 2, repeatedly perform compression on data that has been compressed m-1 times, based on the delta encoding technique; and
based on the mth compression ratio being less than the m-1th compression ratio, stop compression based on the delta encoding technique, and
wherein the m-1th compression ratio is defined as a compression ratio in m-1th compression based on the delta encoding technique, and
wherein the mth compression ratio is defined as a compression ratio in mth compression based on the delta encoding technique.

5. The rendering system of claim 3, wherein the collection server is configured to:
based on a size of the pre-processed data exceeding a critical size, perform n repetitions of compression on the pre-processed data,
wherein n repetitions represent a number of times the compression is performed based on the delta encoding technique such that a compression ratio with respect to the pre-processed data becomes 0.01 or less, and
wherein the critical size is in a range of about 500 megabytes (MB) to about 1 gigabyte (GB).

6. The rendering system of claim 1, wherein the rendering lookup table comprises the rendering rule information for determining to perform the CSR or the SSR, based on domain information about the process data and search period information about the process data,
wherein the domain information about the process data comprises information about a type of the process data, and
wherein the search period information about the process data comprises information about a period during which the process data has been collected.

7. The rendering system of claim 6, wherein the rendering lookup table comprises the rendering rule information for determining to perform the CSR or the SSR, based on process program information about the process data, and
wherein the process program information about the process data comprises information about at least one of a process identifier for the process data or a process recipe identifier for the process data.

8. The rendering system of claim 6, wherein the rendering lookup table comprises the rendering rule information for determining to perform the CSR or the SSR, based on facility information about the process data.

9. The rendering system of claim 6, wherein the rendering lookup table comprises the rendering rule information for determining to perform the CSR or the SSR, based on process step information about the process data.

10. A server device comprising:
a collection server configured to (i) obtain source data from an external data source and (ii) generate, based on the source data, compressed process data and metadata with respect to the compressed process data;
a distributed server configured to store the compressed process data received from the collection server;
a central server configured to store (i) the metadata received from the collection server and (ii) a rendering lookup table; and
a computing server,
wherein the central server is configured to:
receive a rendering request from a client device, and
determine to perform client-side rendering (CSR) or server-side rendering (SSR), based on the rendering request and the rendering lookup table, and
wherein the distributed server is configured to:
based on determining to perform the CSR, transmit the compressed process data to the client device, and
based on determining to perform the SSR, transmit the compressed process data to the computing server, and
wherein the computing server is configured to, based on determining to perform the SSR, receive the compressed process data from the distributed server, decode and render the compressed process data, and transmit the rendered data to the client device, and
wherein the rendering request comprises information about features of process data to be rendered, and
wherein the rendering lookup table comprises rendering rule information for determining to perform the CSR or the SSR, based on the features of the process data.

11. The server device of claim 10, wherein the collection server is configured to:
extract process data from the source data that is obtained from the external data source;
perform pre-processing on the process data to remove noise from the process data;
compress the pre-processed data based on a delta encoding technique;
compress, based on an LZ77 technique, the data that has been compressed based on the delta encoding technique; and
convert, into a string, the data that has been compressed based on the LZ77 technique, thereby generating the compressed process data.

12. The server device of claim 11, wherein the collection server is configured to, based on the delta encoding technique, perform n repetitions of compression on the pre-processed data, where n is a natural number greater than or equal to 2.

13. The server device of claim 12, wherein the collection server is configured to:
based on an mth compression ratio being greater than or equal to an m-1th compression ratio, where m is a natural number greater than or equal to 2, repeatedly perform compression on data that has been compressed m-1 times, based on the delta encoding technique; and
based on the mth compression ratio being less than the m-1th compression ratio, stop compression based on the delta encoding technique, and
wherein the m-1th compression ratio is defined as a compression ratio in m-1th compression based on the delta encoding technique, and
wherein the mth compression ratio is defined as a compression ratio in mth compression based on the delta encoding technique.

14. The server device of claim 12, wherein the collection server is configured to:
based on a size of the pre-processed data exceeding a critical size, perform n repetitions of compression on the pre-processed data,
wherein n repetitions represent a number of times the compression is performed based on the delta encoding technique such that a compression ratio with respect to the pre-processed data becomes 0.01 or less, and
wherein the critical size is in a range of about 500 megabytes (MB) to about 1 gigabyte (GB).

15. The server device of claim 10, wherein the rendering lookup table comprises the rendering rule information for determining to perform the CSR or the SSR, based on domain information about the process data and search period information about the process data,
wherein the domain information about the process data comprises information about a type of the process data, and
wherein the search period information about the process data comprises information about a period during which the process data has been collected.

16. The server device of claim 15, wherein the rendering lookup table comprises the rendering rule information for determining to perform the CSR or the SSR, based on process program information about the process data, and
wherein the process program information about the process data comprises information about at least one of a process identifier for the process data or a process recipe identifier for the process data.

17. The server device of claim 15, wherein the rendering lookup table comprises the rendering rule information for determining to perform the CSR or the SSR, based on at least one of facility information about the process data or process step information about the process data.

18. A client device comprising:
a display;
a storage configured to store a rendering lookup table;
an input interface;
a communication interface configured to communicate with a server device; and
at least one processor,
wherein the at least one processor is configured to:
receive a rendering request from a user via the input interface,
determine to perform client-side rendering (CSR) or server-side rendering (SSR), based on the rendering request and the rendering lookup table,
based on a result of a determination to perform the CSR or the SSR,, receive data corresponding to the result of the determination from the server device via the communication interface, and
based on the received data corresponding to the result of the determination, control the display to display an image corresponding to the rendering request,
wherein the rendering request comprises information about features of process data to be rendered, and
wherein the rendering lookup table comprises rendering rule information for determining to perform the CSR or the SSR, based on the features of the process data.

19. The client device of claim 18, wherein the at least one processor is configured to:
based on determining to perform the CSR, (i) transmit a CSR command to the server device via the communication interface so as to transmit compressed process data, (ii) receive the compressed process data from the server device via the communication interface, (iii) decode and render the compressed process data, and (iv) control the display to display the rendered data; and
based on determining to perform the SSR, (i) transmit an SSR command to the server device via the communication interface so as to transmit rendered data, (ii) receive the rendered data from the server device via the communication interface, and (iii) control the display to display the rendered data.

20. The client device of claim 18, wherein the rendering lookup table comprises rendering rule information for determining to perform the CSR or the SSR, based on at least two of (i) domain information about the process data, (ii) search period information about the process data, (iii) process program information about the process data, (iv) facility information about the process data, or (v) process step information about the process data.
